(19) United States
(12) Patent Application Publication
(10) Pub. No.: US 2020/0132732 A1
(43) Pub. Date: Apr. 30, 2020

(54) CURRENT DETECTION METHOD AND CURRENT DETECTION STRUCTURE

(71) Applicant: Yazaki Corporation, Tokyo (JP)

(72) Inventors: Chihiro ONO, Susono-shi (JP); Hiroki SUGIYAMA, Susono-shi (JP)

(73) Assignee: Yazaki Corporation, Tokyo (JP)

(21) Appl. No.: 16/585,203

(22) Filed: Sep. 27, 2019

(30) Foreign Application Priority Data
Oct. 30, 2018 (JP) 2018-204191

(51) Int. Cl. G01R 19/00; G01R 15/14

(52) U.S. Cl. CPC G01R 19/0092; G01R 15/14

(57) ABSTRACT

A current detection structure comprises, a bus bar to be measured through which a current to be measured flows; an element that detects a magnetic field; and a first proximity bus bar and a second proximity bus bar, wherein arrangements of the first proximity bus bar and the second proximity bus bar relative to the element and the directions and magnitude of currents flowing through the first proximity bus bar and the second proximity bus bar are set such that the magnitude of magnetic fields at the position of the element generated by the first proximity bus bar and the second proximity bus bar are the same and directions thereof are reversed.

### CROSS REFERENCE TO RELATED APPLICATIONS

This application is based on and claims priority from Japanese patent application No. 2018-204191 filed on Oct. 30, 2018, the entire contents of which are incorporated herein by reference.

### BACKGROUND OF THE INVENTION

### 1. Technical Field

The present invention relates to a current detection method and a current detection structure.

### 2. Background Art

A current sensor that detects a current by a magnetic detection element is known (see, for example, Patent Literatures JP-UM-A-5-25369 and JP-A-2002-243766). In addition, Patent Literature JP-A-2005-134343 discloses a magnetic field measuring device in which an outgoing conductor and a returning conductor for passing a current signal are arranged so as to cancel out magnetic fields that are generated by the conductors and sensed by a magnetic sensor.

### SUMMARY

In Patent Literature JP-UM-A-5-25369, a magnetic field from a proximity bus bar current is shielded by a shield, and an element placed in a gap of the shield detects only a magnetic field from the bus bar current to be measured. However, in Patent Literature JP-UM-A-5-25369, the shield is large, leading to increase in the cost.

In Patent Literature JP-A-2002-243766, two magnetic sensors are arranged such that an absolute value of output of the detection current is equal and polarity of the output is opposite, and the influence of the uniform external magnetic field is eliminated by detecting output difference between the two elements. However, in Patent Literature JP-A-2002-243766, only a uniform external magnetic field can be cancelled, and the fluctuation in the external magnetic field cannot be dealt with.

The technique described in Patent Literature JP-A-2005-134343 aims to reduce an error in display of an azimuth sensor by inhibiting a magnetic field generated by a current in a portable device and preventing a geomagnetic sensor from sensing.

The present invention has been made in view of the above circumstances, and an object thereof is to provide a current detection method and a current detection structure that can eliminate the influence of an external magnetic field and detect only a magnetic field generated by a current flowing through a bus bar to be measured without using a shield, even when the external magnetic field fluctuates.

In order to achieve the above object, the current detection method and the current detection structure according to the present invention are characterized by the following (1) to (6).
(1) A current detection method, using a current detection structure including:
   a bus bar to be measured through which a current to be measured flows;
   at least one element that detects a magnetic field generated by the current of the bus bar to be measured; and
   a first proximity bus bar and a second proximity bus bar disposed at positions where the first proximity bus bar and the second proximity bus bar face each other with the bus bar to be measured interposed therebetween,
   the current detection method including
   setting arrangements of the first proximity bus bar and the second proximity bus bar relative to the element and directions and magnitude of currents flowing through the first proximity bus bar and the second proximity bus bar, such that magnitude of magnetic fields at the position of the element generated by the first proximity bus bar and the second proximity bus bar are the same and directions thereof are reversed.
(2) The current detection method according to above (1),
   wherein the first proximity bus bar and the second proximity bus bar are integrated.
(3) The current detection method according to above (1),
   wherein the elements are arranged at positions where the elements face each other with the bus bar to be measured interposed therebetween.
(4) A current detection structure, comprising:
   a bus bar to be measured through which a current to be measured flows;
   at least one element that detects a magnetic field generated by the current of the bus bar to be measured; and
   a first proximity bus bar and a second proximity bus bar arranged at positions where the first proximity bus bar and the second proximity bus bar face each other with the bus bar to be measured interposed therebetween,
   wherein arrangements of the first proximity bus bar and the second proximity bus bar relative to the element and the direction and magnitude of currents flowing through the first proximity bus bar and the second proximity bus bar are set such that magnitude of magnetic fields at the position of the element generated by the first proximity bus bar and the second proximity bus bar are the same and directions thereof are reversed.
(5) The current detection structure according to above (4),
   wherein the first proximity bus bar and the second proximity bus bar are integrated.
(6) The current detection structure according to above (4),
   wherein the elements are arranged at positions where the elements face each other with the bus bar to be measured interposed therebetween.

According to the current detection method of the configuration of the above (1), even when the external magnetic fields generated by the first and second proximity bus bars fluctuate, it is possible to eliminate the influence of the external magnetic fields and detect only the magnetic field generated by the current flowing through the bus bar to be measured without using the shield.

According to the current detection method of the configuration of the above (2), fluctuations in the external magnetic fields generated by the first proximity bus bar and the second proximity bus bar are the same, so that the influences of the external magnetic fields can be eliminated. In addition, the magnitude of currents flowing through the first proximity bus bar and the second proximity bus bar are always equal, so that a current detection structure can be realized with a simple configuration without requiring complicated configuration or control for equalizing the current flowing through the first proximity bus bar and the current flowing through the second proximity bus bar.

According to the current detection method of the configuration of the above (3), measurement accuracy is improved by measuring the magnetic field with the two elements.

According to the current detection structure of the configuration of the above (4), even when the external magnetic fields generated by the first and second proximity bus bars fluctuate, it is possible to eliminate the influence of the external magnetic fields and detect only the magnetic field generated by the current flowing through the bus bar to be measured without using the shield.

According to the current detection structure of the configuration of the above (5), fluctuations in the external magnetic fields generated by the first proximity bus bar and the second proximity bus bar are the same, so that the influence of the external magnetic fields can be eliminated. In addition, the magnitude of currents flowing through the first proximity bus bar and the second proximity bus bar are always equal, so that a current detection structure can be realized with a simple configuration without requiring complicated configuration or control for equalizing the current flowing through the first proximity bus bar and the current flowing through the second proximity bus bar.

According to the current detection structure of the configuration of the above (6), the measurement accuracy is improved by measuring the magnetic field with the two elements.

According to the present invention, even when the external magnetic fields generated by the first and second proximity bus bars fluctuate, it is possible to eliminate the influence of the external magnetic field and detect only the magnetic field generated by the current flowing through the bus bar to be measured without using the shield.

The present invention has been briefly described as above. Details of the present invention will be further clarified by reading a mode for carrying out the present invention described below (hereinafter, referred to as “embodiment”) with reference to the accompanying drawings.

### BRIEF DESCRIPTION OF THE DRAWINGS

FIG. 1 is a diagram for showing a current detection method and a current detection structure according to an embodiment of the present invention.

FIGS. 2A and 2B are diagrams showing an example of a current detection structure according to an embodiment of the present invention.

FIG. 3 is a diagram showing another example of a current detection structure according to an embodiment of the present invention.

### DETAILED DESCRIPTION OF EMBODIMENTS

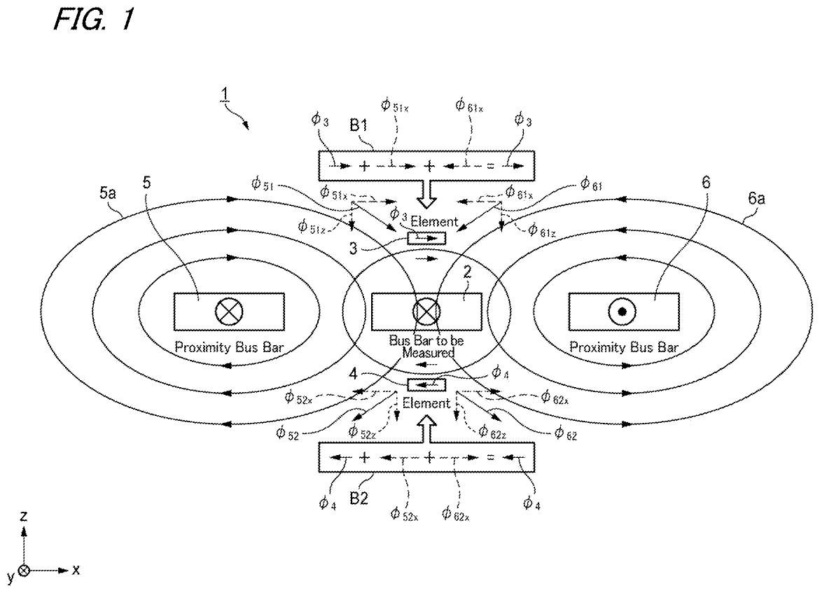

A specific embodiment according to the present invention is described with reference to the drawings. FIG. 1 is a diagram for showing a current detection method and a current detection structure according to an embodiment of the present invention. A current detection structure 1 shown in FIG. 1 includes a bus bar 2 to be measured through which a current to be measured flows, elements 3, 4 for detecting a magnetic field, which is generated, around the bus bar 2 to be measured, by the current flowing through the bus bar 2 to be measured, and proximity bus bars 5, 6 (first proximity bus bar, second proximity bus bar) that are located at opposite sides relative to a vertical plane (zy plane in FIG. 1) extending along a center line of the bus bar 2 to be measured in a longitudinal direction (y-axis direction in FIG. 1). That is, the proximity bus bars 5, 6 are arranged at positions where they face each other with the bus bar 2 to be measured interposed therebetween. In the present embodiment, the center line of the bus bar 2 to be measured in the longitudinal direction is parallel to center lines of the proximity bus bars 5, 6 in the longitudinal directions (y-axis direction in FIG. 1) in the same plane (xy plane in FIG. 1). The elements 3, 4 are arranged such that a magneto-sensitive axis is parallel to an arrangement direction of the bus bars 2 to be measured and the proximity bus bars 5, 6 (x direction in FIG. 1) and is perpendicular to the center lines of the bus bars in the longitudinal directions. The elements 3, 4 constitute a part of a current sensor and output a signal according to a magnitude of a detected magnetic field. In the current detection structure 1, arrangements of the proximity bus bar 5 and the proximity bus bar 6 relative to the elements 3, 4 and the direction and the magnitude of the current flowing through the proximity bus bar 5 and the proximity bus bar 6 are set such that magnitude of magnetic fields generated by the proximity bus bar 5 and the proximity bus bar 6 at positions of the elements 3, 4 are the same, and the directions of the magnetic fields are reversed. The elements 3, 4 are located at opposite sides relative to a plane (xy plane in FIG. 1) that passes through the center line of the bus bar 2 to be measured in the longitudinal direction and is perpendicular to the vertical plane extending along the center line thereof. That is, the elements 3, 4 are arranged at positions where they face each other with the bus bar 2 to be measured interposed therebetween. The directions of the currents flowing through the proximity bus bars 5, 6 are made opposite to each other in the current detection structure 1, and thereby the influence of external magnetic fields can be eliminated even when the external magnetic fields generated by the proximity bus bars 5, 6 fluctuate. Therefore, according to the current detection structure 1, it is possible to eliminate the influence of the external magnetic field and detect only the magnetic field generated by the current flowing through the bus bar 2 to be measured without using a shield.

Specifically, the proximity bus bar 5, 6 are arranged on both sides of the bus bar 2 to be measured. Currents in the proximity bus bars 5, 6 flow in parallel to the current flowing through the bus bar 2 to be measured. The elements 3, 4 are located at the upper side and the lower side of the bus bar 2 to be measured, respectively. Distances from the bus bar 2 to be measured to the positions of the elements 3, 4 are exactly the same. The element 3 detects both a magnetic field ϕ3 generated by the current flowing through the bus bar 2 to be measured and magnetic fields ϕ51, ϕ61 respectively generated by currents flowing through the proximity bus bars 5, 6. The element 4 detects both a magnetic field ϕ4 generated by the current flowing through the bus bar 2 to be measured and magnetic fields ϕ52, ϕ62 respectively generated by currents flowing through the proximity bus bars 5, 6. The magnetic field is measured with the two elements 3, 4, so that measurement accuracy is improved. The proximity bus bars 5, 6 are arranged at the same distance from the elements 3, 4. The currents having the same current value and opposite directions flow through the proximity bus bars 5, 6. Therefore, magnetic fields 5a, 6a respectively generated by currents flowing through the proximity bus bars 5, 6 are cancelled out, and the elements 3, 4 can detect only the magnetic field generated by the current flowing through the bus bar 2 to be measured. In detail, the element 3 detects the magnetic field ϕ3 generated by the current flowing through the bus bar 2 to be measured and x-direction components ϕ51x, ϕ61x of the magnetic fields ϕ51, ϕ61 generated by currents flowing through the proximity bus bars 5, 6. As shown in Equation B1 of FIG. 1, the magnetic fields ϕ51x, ϕ61x are mutually cancelled out at the position of the element 3 because the intensities thereof are the same and the directions thereof are reversed, so that only the magnetic field ϕ3 generated by the current flowing through the bus bar 2 to be measured is detected in the element 3. Similarly, the element 4 detects the magnetic field ϕ4 generated by the current flowing through the bus bar 2 to be measured and the x-direction components ϕ52x, ϕ62x of the magnetic fields ϕ52, ϕ62 generated by the currents flowing through the proximity bus bars 5, 6.

As shown in Equation B2 of FIG. 1, the magnetic fields ϕ52x, ϕ62x are mutually cancelled out at the position of the element 4 because the intensities thereof are the same and the directions thereof are reversed, so that only the magnetic field ϕ4 generated by the current flowing through the bus bar 2 to be measured is detected in the element 4.

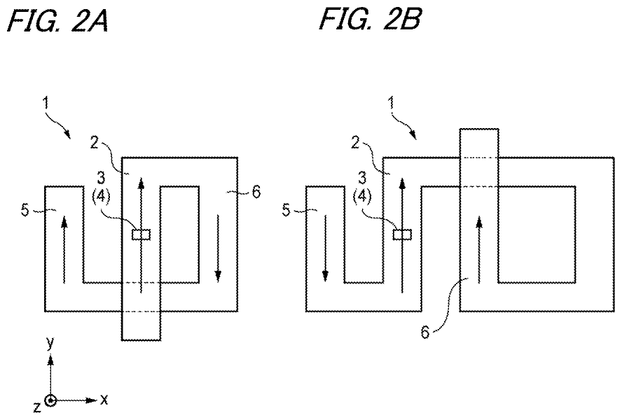

FIGS. 2A and 2B are diagrams showing an example of a current detection structure according to an embodiment of the present invention. As shown in FIGS. 2A and 2B, for example, the bus bar 2 to be measured and the proximity bus bars 5, 6 are integrated and are connected so as to form one current path in the current detection structure 1 shown in FIG. 1. Hereinafter, an upstream side and a downstream side of the currents flowing through the bus bar 2 to be measured and the proximity bus bars 5, 6 are simply referred to as an upstream side and a downstream side. In FIG. 2A, one end of the bus bar 2 to be measured on a downstream side is connected to one end of the proximity bus bar 6 on an upstream side, and one end of the proximity bus bar 5 on an upstream side is connected to one end of the proximity bus bar 6 on a downstream side. In addition, in FIG. 2B, one end of the proximity bus bar 5 on a downstream side is connected to one end of the bus bar 2 to be measured on an upstream side, and one end of the bus bar 2 to be measured on a downstream side is connected to one end of the proximity bus bar 6 on an upstream side via a U-shaped bus bar. In FIGS. 2A and 2B, the distances between the proximity bus bars 5, 6 and the elements 3, 4 are the same, the magnitude of the currents flowing through the proximity bus bar 5, 6 is the same, and the directions of the currents are opposite.

The bus bar located on the rightmost side in FIG. 2B, that is, a part that connects the bus bar 2 to be measured with the proximity bus bar 6 and is parallel to the bus bar 2 to be measured and the proximity bus bar 6, is sufficiently separated from the bus bar 2 to be measured so that the generated magnetic field does not affect the measurement results of the elements 3, 4. Distance between these bus bars and the bus bar 2 to be measured may be set so as to cancel out the synthetic magnetic field of the bus bar and the proximity bus bar 5 and the magnetic field of the proximity bus bar 6 at the positions of the elements 3, 4.

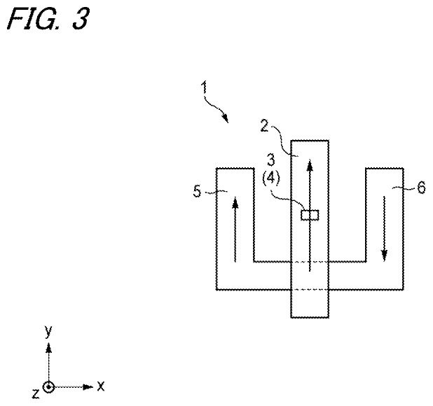

FIG. 3 is a diagram showing another example of a current detection structure according to an embodiment of the present invention. In the current detection structure 1 shown in FIG. 3, the bus bar 2 to be measured is not connected to the proximity bus bars 5, 6, and forms an independent current path. Even in this case, magnetic fields generated by the currents flowing through the proximity bus bars 5, 6 are cancelled out and only the magnetic field generated by the current flowing through the bus bar 2 to be measured can be detected in elements 3, 4 when the distances between the proximity bus bars 5, 6 and the elements 3, 4 are the same, and the magnitude of currents flowing through the proximity bus bars 5, 6 are the same and the directions of the currents are opposite. It should be noted that the proximity bus bars 5, 6 may not necessarily be connected with each other.

According to the present embodiment, even when the external magnetic fields generated by the proximity bus bars 5, 6 fluctuate, it is possible to eliminate the influence of the external magnetic fields and detect only the magnetic field generated by the current flowing through the bus bar 2 to be measured without using the shield. In addition, when the proximity bus bars 5, 6 are connected, fluctuations in the external magnetic fields generated by the proximity bus bars 5, 6 are the same. Accordingly, the influences of the external magnetic fields can be eliminated. An example in which the magnetic field is detected by the two elements 3, 4 has been described in the present embodiment, but one element for detecting a magnetic field may be used. Even when there is one element, the arrangement of the proximity bus bars 5, 6 relative to the element and the directions and magnitude of the currents flowing through the proximity bus bars 5, 6 are set such that the magnitude of the magnetic fields at a position of the element generated by the proximity bus bars 5, 6 are the same and the directions thereof are reversed. Accordingly, only the magnetic field generated by the current flowing through the bus bar 2 to be measured can be measured without using the shield. The current detection method and the current detection structure of the present embodiment are useful as, for example, a current sensor that detects a current flowing through a bus bar connecting an in-vehicle battery of an automobile with a vehicle electrical component.

Here, the characteristics of the embodiments of the current detection method and the current detection structure according to the present invention are briefly summarized in the following [1] to [6].

[1] Provided is a current detection method, using a current detection structure (1) including:

a bus bar (2) to be measured through which a current to be measured flows;

at least one element (3, 4) that detect a magnetic field generated by the current of the bus bar to be measured; and

a first proximity bus bar (proximity bus bar 5) and a second proximity bus bar (proximity bus bar 6) arranged at positions where they face each other with the bus bar to be measured interposed therebetween,

the current detection method including

setting arrangements of the first proximity bus bar and the second proximity bus bar relative to the element and directions and magnitude of currents flowing through the first proximity bus bar and the second proximity bus bar, such that magnitude of magnetic fields at the position of the element generated by the first proximity bus bar and the second proximity bus bar are the same and directions thereof are reversed.

[2] In current detection method according to [1],

the first proximity bus bar and the second proximity bus bar are integrated.

[3] In the current detection method according to [1],

the elements are arranged at positions where the elements face each other with the bus bar to be measured interposed therebetween.

[4] Provided is a current detection structure (1) including:

a bus bar (2) to be measured through which a current to be measured flows;

at least one element (3, 4) that detect a magnetic field generated by the current of the bus bar to be measured; and

a first proximity bus bar (5) and a second proximity bus bar (6) arranged at positions where they face each other with the bus bar to be measured interposed therebetween,

in which arrangements of the first proximity bus bar and the second proximity bus bar relative to the element and the directions and magnitude of currents flowing through the first proximity bus bar and the second proximity bus bar are set such that the magnitude of magnetic fields at the position of the element generated by the first proximity bus bar and the second proximity bus bar are the same and directions thereof are reversed.

[5] In the current detection structure according to [4],

the first proximity bus bar and the second proximity bus bar are integrated.

[6] In the current detection structure according to [4],

the elements are arranged at positions where they face each other with the bus bar to be measured interposed therebetween.

What is claimed is:

1. A current detection method, using a current detection structure comprising:
a bus bar to be measured through which a current to be measured flows;
at least one element that detects a magnetic field generated by the current of the bus bar to be measured; and
a first proximity bus bar and a second proximity bus bar disposed at positions where the first proximity bus bar and the second proximity bus bar face each other with the bus bar to be measured interposed therebetween,
the current detection method including
setting arrangements of the first proximity bus bar and the second proximity bus bar relative to the element and directions and magnitude of currents flowing through the first proximity bus bar and the second proximity bus bar, such that magnitude of magnetic fields at the position of the element generated by the first proximity bus bar and the second proximity bus bar are the same and directions thereof are reversed.

2. The current detection method according to claim 1,
wherein the first proximity bus bar and the second proximity bus bar are integrated.

3. The current detection method according to claim 1,
wherein the elements are arranged at positions where the elements face each other with the bus bar to be measured interposed therebetween.

4. A current detection structure, comprising:
a bus bar to be measured through which a current to be measured flows;
an element that detects a magnetic field generated by the current of the bus bar to be measured; and
a first proximity bus bar and a second proximity bus bar arranged at positions where the first proximity bus bar and the second proximity bus bar face each other with the bus bar to be measured interposed therebetween,
wherein arrangements of the first proximity bus bar and the second proximity bus bar relative to the element and the direction and magnitude of currents flowing through the first proximity bus bar and the second proximity bus bar are set such that magnitude of magnetic fields at the position of the element generated by the first proximity bus bar and the second proximity bus bar are the same and directions thereof are reversed.

5. The current detection structure according to claim 4,
wherein the first proximity bus bar and the second proximity bus bar are integrated.

6. The current detection structure according to claim 4,
wherein the elements are arranged at positions where the elements face each other with the bus bar to be measured interposed therebetween.
